(19) United States
(12) Patent Application Publication
(10) Pub. No.: US 2022/0285916 A1
(43) Pub. Date: Sep. 8, 2022

(54) SEMICONDUCTOR LASER DEVICE

(71) Applicant: Panasonic Corporation, Osaka (JP)

(72) Inventor: Hideo YAMAGUCHI, Kyoto (JP)

(21) Appl. No.: 17/633,305

(22) PCT Filed: Sep. 9, 2020
(86) PCT No.: PCT/JP2020/034041

§ 371 Date: Feb. 7, 2022

(30) Foreign Application Priority Data
Sep. 13, 2019 (JP) 2019-167197

(51) Int. Cl. H01S 5/14; H01S 5/40

(52) U.S. Cl. CPC H01S 5/142; H01S 5/4025

(57) ABSTRACT

A semiconductor laser device includes: a plurality of semiconductor light emitting elements each of which emits a light beam; a wavelength dispersion element (a diffraction grating) that emits the light beam emitted from each of the plurality of semiconductor light emitting elements to pass through one optical path; a pedestal that supports the wavelength dispersion element; and a presser that fixes the wavelength dispersion element to the pedestal by pressing the wavelength dispersion element. The presser presses on the wavelength dispersion element in a direction perpendicular to a surface on which with the wavelength dispersion element is provided.

### CROSS-REFERENCE OF RELATED APPLICATIONS

This application is the U.S. National Phase under 35 U.S.C. § 371 of International Patent Application No. PCT/JP2020/034041, filed on Sep. 9, 2020, which in turn claims the benefit of Japanese Application No. 2019-167197, filed on Sep. 13, 2019, the entire disclosures of which applications are incorporated by reference herein.

### TECHNICAL FIELD

The present disclosure relates to a semiconductor laser device

### BACKGROUND ART

Conventionally, there is an external resonator type semiconductor laser device that resonates outside the semiconductor light emitting element (see, for example, Patent Literature (PTL) 1).

The conventional semiconductor laser device disclosed in PTL 1 includes a first semiconductor light emitting element, a second semiconductor light emitting element, a wavelength dispersion element, and a partially reflecting mirror.

The light emitted from each of the first light emitting point of the first semiconductor light emitting element and the second light emitting point of the second semiconductor light emitting element is superimposed on one beam due to the wavelength dispersion effect of the wavelength dispersion element and is irradiated to the partially reflecting mirror.

Part of the light irradiated to the partially reflecting mirror is transmitted and emitted from the partially reflecting mirror as a normal oscillation output beam (laser beam). The remaining part is reflected by the partially reflecting mirror.

The light reflected by the partially reflecting mirror propagates on the same optical path as the light from the first light emitting point and the second light emitting point to the partially reflecting mirror in the opposite direction, and returns to the first light emitting point and the second light emitting point. Accordingly, an external laser resonator (external resonator) is formed between (i) the first semiconductor light emitting element and the second semiconductor light emitting element and (ii) the partially reflecting mirror via a wavelength dispersion element (in other words, a diffraction grating).

The laser beam emitted through the partially reflecting mirror is a laser beam in which two beams from the first light emitting point and the second light emitting point are superimposed by the wavelength dispersion element and pass on one optical path. For that reason, in the conventional semiconductor laser device, the luminance can be approximately doubled by the first semiconductor light emitting element and the second semiconductor light emitting element as compared with the case of one semiconductor light emitting element.

### CITATION LIST

### Patent Literature

### [PTL 1] Japanese Patent No. 6289640

### [PTL 2] Japanese Unexamined Patent Application Publication No. 2000-137139

### SUMMARY OF DISCLOSURE

### Technical Problem

In the state where the external resonator is formed (that is, the state in which the resonance of light beams occurs), the wavelengths of the respective light beams emitted from the first light emitting point and the second light emitting point are automatically determined so that the normal oscillation output beams resonate on one optical path between the partially reflecting mirror and the wavelength dispersion element.

Here, when two light beams are caused to multiplex with each other using a wavelength dispersion element (that is, two light beams are caused to pass on one optical path), if the intervals of a plurality of grooves formed in the wavelength dispersion element change on the order of submicron due to the heat of light beams and/or the disturbance, the wavelength of the light beam returned from the partially reflecting mirror to the semiconductor light emitting element is greatly deviated. When the wavelength of the light beam deviates, an optical path in which beams are incident and emitted each other is formed between the first semiconductor light emitting device and the second semiconductor light emitting element, and an unintended light resonance may occur in the optical path.

Accordingly, there is a possibility that the amplified spontaneous emission (ASE) boundary of the laser beam is exceeded, and the intended resonance does not occur between the partially reflecting mirror and the semiconductor light emitting element, and/or the resonance becomes unstable. In addition, in such a case, there is a possibility that the optical output of the laser beam emitted from the partially reflecting mirror decreases due to the occurrence of unintended resonance.

The present disclosure provides a semiconductor laser device capable of suppressing the occurrence of unintended resonance.

### Solution to Problem

The semiconductor laser device according to one aspect of the present disclosure includes: a plurality of amplifiers each of which emits a light beam; a diffraction grating that guides the light beam emitted from each of the plurality of amplifiers to pass through one optical path; a pedestal that supports the diffraction grating; and a presser that fixes the diffraction grating to the pedestal by pressing on the diffraction grating, wherein the presser presses on the diffraction grating in a direction perpendicular to a surface on which the diffraction grating is provided.

### Advantageous Effects of Disclosure

According to the semiconductor laser device according to one aspect of the present disclosure, it is possible to suppress the occurrence of unintended resonance.

### BRIEF DESCRIPTION OF DRAWINGS

FIG. 1 is a perspective view showing a semiconductor laser device according to Embodiment 1.

FIG. 2 is a schematic diagram for explaining the resonance of light beams in the semiconductor laser device according to Embodiment 1.

FIG. 3A is a perspective view showing the main surface side of the multiplexer included in the semiconductor laser device according to Embodiment 1.

FIG. 3B is a rear view showing the multiplexer included in the semiconductor laser device according to Embodiment 1.

FIG. 3C is a perspective view showing the back surface side of the multiplexer included in the semiconductor laser device according to Embodiment 1.

FIG. 3D is a cross-sectional view showing the multiplexer of the semiconductor laser device according to Embodiment 1 in the line IIID-IIID in FIG. 3B.

FIG. 4 is a perspective view showing a manufacturing process of a semiconductor element unit included in the semiconductor laser device according to Embodiment 1.

FIG. 5 is an exploded perspective view showing an optical unit included in the semiconductor laser device according to Embodiment 1.

FIG. 6 is a cross-sectional view showing a multiplexer according to Variation 1 of Embodiment 1.

FIG. 7A is a perspective view showing the main surface side of a multiplexer according to Variation 2 of Embodiment 1.

FIG. 7B is a rear view showing the multiplexer according to Variation 2 of Embodiment 1.

FIG. 7C is a perspective view showing the back surface side of the multiplexer according to Variation 2 of Embodiment 1.

FIG. 7D is a cross-sectional view showing the multiplexer according to Variation 2 of Embodiment 1 in the VIID-VIID line in FIG. 7B.

FIG. 8A is a perspective view showing the main surface side of a multiplexer according to Variation 3 of Embodiment 1.

FIG. 8B is a rear view showing the multiplexer according to Variation 3 of Embodiment 1.

FIG. 8C is a perspective view showing the back surface side of the multiplexer according to Variation 3 of Embodiment 1.

FIG. 8D is a cross-sectional view showing the multiplexer according to Variation 3 of Embodiment 1 in the VIIID-VIIID line in FIG. 8B.

FIG. 9 is a perspective view showing a semiconductor laser device according to Embodiment 2.

FIG. 10 is a schematic diagram for explaining the resonance of light beams in the semiconductor laser device according to Embodiment 2.

FIG. 11A is a perspective view showing the main surface side of the multiplexer included in the semiconductor laser device according to Embodiment 2.

FIG. 11B is a front view showing the multiplexer included in the semiconductor laser device according to Embodiment 2.

FIG. 11C is a cross-sectional view showing the multiplexer of the semiconductor laser device according to Embodiment 2 in the XID-XID line in FIG. 11B.

FIG. 12 is a cross-sectional view showing a multiplexer according to a variation of Embodiment 2.

FIG. 13 is a perspective view showing a semiconductor laser device according to Embodiment 3.

FIG. 14 is a perspective view showing an amplifier included in the semiconductor laser device according to Embodiment 3.

FIG. 15 is a schematic diagram for explaining the resonance of light beams in the semiconductor laser device according to Embodiment 3.

### DESCRIPTION OF EMBODIMENTS

Hereinafter, embodiments of the present disclosure will be described in detail with reference to the drawings. It should be noted that each of the embodiments described below shows a specific example of the present disclosure. The numerical values, shapes, materials, components, arrangement positions and connection forms of the components, steps, the order of steps, and the like shown in the following embodiments are examples, and are not intended to limit the present disclosure.

It should be noted that each figure is a schematic diagram and is not necessarily exactly illustrated. Therefore, for example, the scales and the like do not always match in each figure. In addition, in each figure, the same reference numerals are given to substantially the same configurations, and duplicate explanations for substantially the same configurations may be omitted or simplified.

In addition, in the following embodiments, the terms “upper”, “upward”, and “above” and “lower”, “downward”, and “below” do not refer to the upward direction (vertically upward) and the downward direction (vertically downward) in absolute spatial recognition, respectively. In addition, the terms the terms “upper”, “upward”, and “above” and “lower”, “downward”, and “below” are applied to not only the case that the two components are spaced apart from each other and another component exists between the two components, but also the case that the two components are placed in close contact with each other and the two components touch each other.

In addition, in the present specification and the drawings, the X-axis, the Y-axis, and the Z-axis indicate the three axes of the three-dimensional Cartesian coordinate system. In each embodiment, the Y-axis direction is the vertical direction, and the direction perpendicular to the Y-axis (the direction parallel to the XZ plane) is the horizontal direction.

In addition, in the embodiment described below, the positive direction of the Y-axis may be described as upward and the negative direction of the Y-axis may be described as downward.

In addition, in the embodiment described below, “top view” refers to when the main surface is viewed from the normal direction of the main surface of the base.

### Embodiment 1

### [Configuration]

### <Overall Configuration>

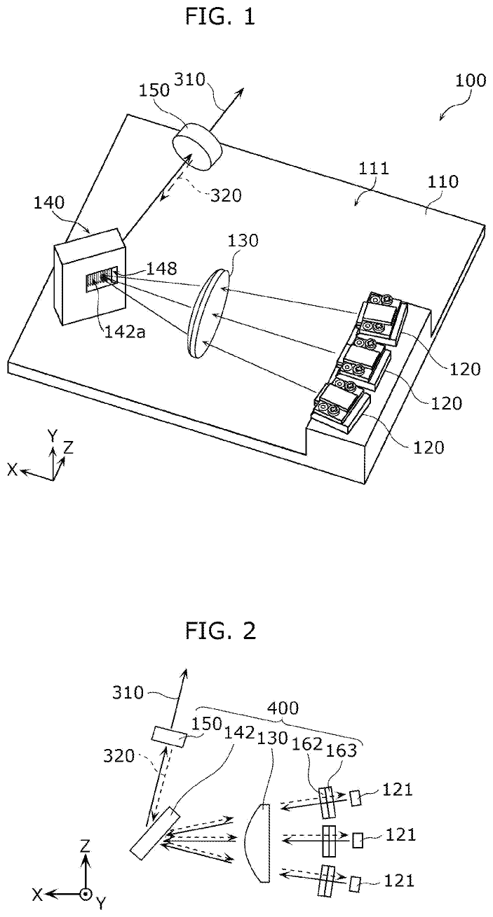

FIG. 1 is a schematic perspective view showing semiconductor laser device 100 according to Embodiment 1. FIG. 2 is a schematic diagram for explaining the resonance of light beams in semiconductor laser device 100 according to Embodiment 1.

Semiconductor laser device 100 is an external resonator type laser device that emits laser beam 310 using external resonator 400. Semiconductor laser device 100 is used, for example, as a light source of a processing device for laser processing an object.

Semiconductor laser device 100 includes base 110, a plurality of semiconductor element units 120, coupling optical system 130, multiplexer 140, and partially reflecting mirror 150.

Base 110 is a table on which various components included in semiconductor laser device 100 are placed. Specifically, semiconductor element unit 120, coupling optical system 130, multiplexer 140, and partially reflecting mirror 150 are mounted on main surface 111 of base 110 (the upper surface of base 110).

It should be noted that the material adopted for base 110 is not particularly limited. The material adopted for base 110 may be, for example, a metal material, a resin material, or a ceramic material.

In addition, the shape of base 110 is not particularly limited. In the present embodiment, base 110 is rectangular in a top view. In addition, the portion on which semiconductor element unit 120 is placed is higher on the Y-axis positive direction side than the other portions.

Semiconductor element unit 120 is a light source unit including semiconductor light emitting element (amplifier) 121 that emits a light beam. The light beam emitted from each of the plurality of semiconductor element units 120 (specifically, the plurality of semiconductor light emitting elements 121) is irradiated to partially reflecting mirror 150 through fast axis collimator lens 163, 90 degree image rotation optical system 162, coupling optical system 130, and multiplexer 140. Part of the light irradiated to partially reflecting mirror 150 is transmitted and emitted from partially reflecting mirror 150 as a normal oscillation output beam (laser beam 310), and the other part is reflected and emitted from partially reflecting mirror 150 to become reflected light 320.

Reflected light 320 reflected by partially reflecting mirror 150 propagates in the opposite direction in the same optical path as the light directed from semiconductor element unit 120 (specifically, semiconductor light emitting element 121) to partially reflecting mirror 150. For example, in FIG. 2, the light beams directed from semiconductor light emitting elements 121 toward partially reflecting mirror 150 are indicated by solid line arrows, and the light beams directed from partially reflecting mirror 150 toward semiconductor light emitting elements 121 are indicated by broken line arrows.

Accordingly, between semiconductor light emitting element 121 and partially reflecting mirror 150 through coupling optical system 130, the wavelength dispersion element (diffraction grating) 142 included in multiplexer 140, 90 degree image rotation optical system 162, and fast axis collimator lens 163, the resonance of light beams occurs, in other words, an external laser resonator (external resonator 400) is formed. Part of the resonated light is emitted as laser beam 310 from partially reflecting mirror 150.

It should be noted that the wavelength of laser beam 310 emitted by semiconductor laser device 100 may be arbitrarily set.

In the present embodiment, semiconductor laser device 100 includes three semiconductor element units 120. Each of the three semiconductor element units 120 includes one semiconductor light emitting element 121 that resonates light between the one semiconductor light emitting element 121 and partially reflecting mirror 150 through coupling optical system 130, multiplexer 140, and the like.

In addition, semiconductor light emitting element 121 emits a laser beam by generating light resonance between semiconductor light emitting element 121 and external resonator 400. At this time, in the present embodiment, semiconductor light emitting element 121 emits a laser beam so that the Y-axis direction is the fast axis.

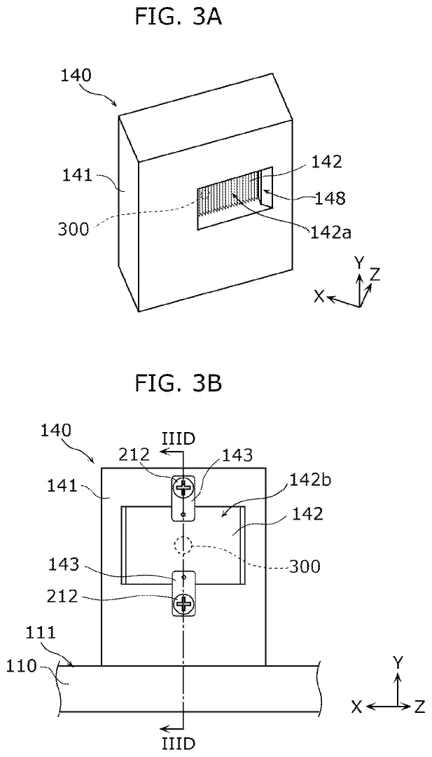

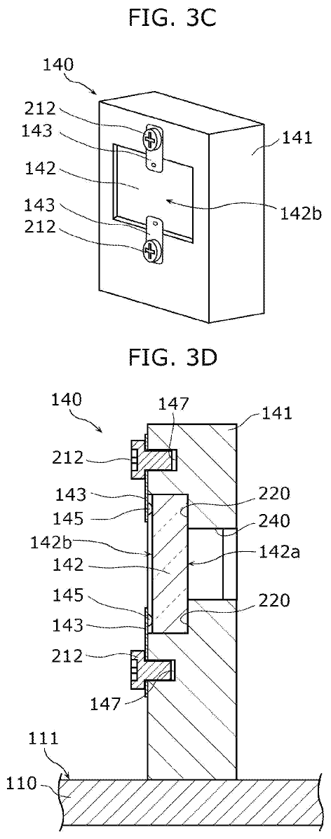

Coupling optical system 130 is an optical member which is disposed between the plurality of semiconductor light emitting elements 121 and wavelength dispersion element 142, and superimposes the light emitted from each of the plurality of semiconductor light emitting elements 121 to main surface 142a of wavelength dispersion element 142 (see FIG. 3A). Specifically, coupling optical system 130 superimposes the light emitted from each of three semiconductor element units 120 on the same position on main surface 142a of wavelength dispersion element 142 included in multiplexer 140. In the present embodiment, coupling optical system 130 is one convex lens. Coupling optical system 130 collects the light emitted from each of the three semiconductor element units 120 on wavelength dispersion element 142.

Coupling optical system 130 is disposed on the optical path of the resonated light beam generated by external resonator 400, and between the plurality of semiconductor light emitting elements 121 and wavelength dispersion element 142. In the present embodiment, coupling optical system 130 is disposed between fast axis collimator lens 163 and wavelength dispersion element 142. More specifically, coupling optical system 130 is disposed between 90 degree image rotation optical system 162 and wavelength dispersion element 142.

It should be noted that in the present embodiment, semiconductor laser device 100 includes one convex lens as coupling optical system 130, but the shape of the lens, the number of lenses, and the like of coupling optical system 130 included in semiconductor laser device 100 are not particularly limited.

Multiplexer 140 is an optical member including wavelength dispersion element 142 that multiplexes and emits a light beam beams which are emitted from coupling optical system 130 and passes through the different optical paths from one another so as to pass through one optical path. Multiplexer 140 includes wavelength dispersion element 142 in which a plurality of grooves are formed on main surface 142a, and multiplexes and emits a plurality of light beams each of which passes through a different optical path from one another so as to pass through one optical path by wavelength dispersion element 142 refracting and emitting the light beams, which are incident from different directions and have different wavelengths, to the respective different angles.

In a state where the resonance of the light beams is generated between the plurality of semiconductor element units 120 and partially reflecting mirror 150, the wavelength of the light beam emitted by each of the plurality of semiconductor element units 120 is automatically determined so that the light beams pass through one optical path to generate the resonance of the light beam between partially reflecting mirror 150 and multiplexer 140. In addition, since the light beams emitted from the respective semiconductor element units 120 are incident on multiplexer 140 (more specifically, wavelength dispersion element 142) from mutually different directions, the respective wavelengths of the light beams emitted from the respective semiconductor element units 120 are different from one another.

For that reason, multiplexer 140 multiplexes and emits light beams emitted from the respective semiconductor element units 120, which are incident from different directions and have different wavelengths, so as to pass through one optical path.

Partially reflecting mirror 150 is an optical member that transmits and emits one part of the light, and reflects and emits the other part of the light. Specifically, partially reflecting mirror 150 reflects several % to several tens of % of the total light output in the light multiplexed by multiplexer 140, and transmits the remaining several % to several tens of %.

It should be noted that the light reflectance of partially reflecting mirror 150 is not particularly limited. For example, the light reflectance of the partially reflecting mirror may be 50% or more, or may be less than 50%.

In the present embodiment, as shown in FIG. 2, external resonator 400 is formed by fast axis collimator lens 163, 90 degree image rotation optical system 162, wavelength dispersion element 142, and partially reflecting mirror 150. In other words, external resonator 400 includes fast axis collimator lens 163, 90 degree image rotation optical system 162, wavelength dispersion element 142, and partially reflecting mirror 150.

90 degree image rotation optical system 162 is an optical element that rotates the spot of light beam emitted from semiconductor light emitting element 121 by 90 degrees. Specifically, 90 degree image rotation optical system 162 interchanges the fast axis direction and the slow axis direction of the light beam emitted from fast axis collimator lens 163. 90 degree image rotation optical system 162 is, for example, a beam twister (BT). 90 degree image rotation optical system 162 and fast axis collimator lens 163 are also referred to as a beam twisted lens unit (BTU). In addition, for example, 90 degree image rotation optical system 162 may be an optical luminous flux transducer disclosed in PTL 2.

One part of 90 degree image rotation optical system 162 is fixed to optical holder 161 and the other part is fixed to fast axis collimator lens 163.

Fast axis collimator lens 163 is a lens that collimates the light beam in the fast axis direction emitted from each of the plurality of semiconductor light emitting elements 121.

The light beam emitted from semiconductor light emitting element 121 is collimated by fast axis collimator lens 163 to become parallel light, and furthermore, each light spot is rotated by 90 degrees by 90 degree image rotation optical system 162. In other words, the fast axis and the slow axis in the light beam emitted from semiconductor light emitting element 121 are interchanged by 90 degree image rotation optical system 162. For that reason, for example, the light beam emitted from semiconductor light emitting element 121 passes through optical unit 160 to be collimated in the horizontal direction and become a light beam whose vertical direction is the slow axis direction.

### <Multiplexer>

Subsequently, the configuration of multiplexer 140 will be described in detail with reference to FIG. 3A to FIG. 3D. FIG. 3A is a perspective view showing main surface 142a side of multiplexer 140. FIG. 3B is a rear view showing multiplexer 140. FIG. 3C is a perspective view showing back surface 142b side of multiplexer 140. FIG. 3D is a cross-sectional view showing multiplexer 140 in the line IIID-IIID in FIG. 3B.

It should be noted that FIG. 3B is a diagram showing the case where multiplexer 140 is viewed from the normal direction of the surface of wavelength dispersion element 142 on the side where the light beam emitted from semiconductor element unit 120 is incident (in other words, the thickness direction of wavelength dispersion element 142).

As shown in FIG. 3A to FIG. 3D, multiplexer 140 includes pedestal 141, wavelength dispersion element 142, presser 143, and adjusting screw 212.

Pedestal 141 is a mount on which wavelength dispersion element 142 is placed. Pedestal 141 fixes wavelength dispersion element 142 at an arbitrary height. Pedestal 141 is placed on main surface 111 of base 110 and fixed to base 110. In the present embodiment, pedestal 141 is formed with through hole 240 penetrating in the thickness direction. Wavelength dispersion element 142 is disposed in through hole 240.

In addition, the diameter of through hole 240 is different between the side where the light beam from semiconductor light emitting element 121 is irradiated and the side where the light beam is transmitted and emitted to partially reflecting mirror 150. In the present embodiment, the diameter of through hole 240 is smaller on the side where the light beam from semiconductor light emitting element 121 is irradiated than on the side where the light beam is transmitted and emitted to partially reflecting mirror 150. In addition, wavelength dispersion element 142 is disposed in through hole 240 on the side where the light beam from semiconductor light emitting element 121 is irradiated, and is fixed to pedestal 141 by presser 143 abutting against abutting portion 220 of pedestal 141.

In addition, pedestal 141 includes inclined portion 148 on the peripheral edge of through hole 240 on the side where the light beam from semiconductor light emitting element 121 is irradiated on main surface 142a of wavelength dispersion element 142.

Inclined portion 148 is an inclined surface formed on pedestal 141b. Inclined portion 148 is inclined, for example, in a top view with respect to the normal direction of main surface 142a of wavelength dispersion element 142. Light beams from semiconductor light emitting elements 121 are incident on wavelength dispersion element 142 from a plurality of directions. Since pedestal 141 includes inclined portion 148, wavelength dispersion element 142 can be irradiated with the light beams from semiconductor light emitting elements 121 at a wider angle with respect to the normal direction of main surface 142a without irradiating pedestal 141.

It should be noted that pedestal 141 may be fixed to base 110 with an adhesive or the like, or may be integrally formed with base 110.

The material adopted for pedestal 141 is not particularly limited. The material adopted for pedestal 141 may be, for example, a metal material or a ceramic material.

Wavelength dispersion element 142 is a diffraction grating (optical element) in which a plurality of irregularities extending in the first direction are alternately formed on main surface 142a of wavelength dispersion element 142. Specifically, wavelength dispersion element 142 has a plate shape, and a plurality of grooves extending in the first direction are provided side by side on main surface 142a in a direction orthogonal to the first direction. In the present embodiment, the first direction is the Y-axis direction. It should be noted that the first direction may be arbitrarily determined, and may be, for example, a direction intersecting the Y axis.

For example, wavelength dispersion element 142 is irradiated with the light beam emitted from each of the plurality of semiconductor element units 120 in the central portion of main surface 142a. For that reason, one light spot 300 formed by superimposing a plurality of light beams emitted from fast axis collimator lenses 163 is located in the central portion of main surface 142a of wavelength dispersion element 142. Wavelength dispersion element 142 multiplexes the light beam emitted from each of the plurality of semiconductor element units 120 and emits the light beams from back surface 142b toward partially reflecting mirror 150 so as to pass through one optical path. In this way, wavelength dispersion element 142 emits the plurality of light beams by aligning their respective optical axes.

It should be noted that in light spot 300, it is advised that the optical axes of the plurality of light beams emitted from fast axis collimator lenses 163 are overlapped on main surface 142a (more specifically, the surface on which the grooves (irregularities) are formed) of wavelength dispersion element 142. In addition, in light spot 300, it is not necessary that the plurality of light beams emitted from fast axis collimator lenses 163 are completely superimposed, and it is only needed that at least a part of the light beam of each of the plurality of light beams emitted from fast axis collimator lenses 163 is superimposed.

In addition, wavelength dispersion element 142 emits reflected light beam 320 reflected by partially reflecting mirror 150 toward each of semiconductor element units 120. Specifically, wavelength dispersion element 142 demultiplexes reflected light beam 320 and emits the demultiplexed light beam toward each of semiconductor element units 120 so that the light beam passes through the original optical path of the light beam emitted from each of semiconductor element units 120.

The material adopted for wavelength dispersion element 142 is not particularly limited. Wavelength dispersion element 142 is formed from, for example, a resin material, glass, or the like. In the present embodiment, wavelength dispersion element 142 is formed of a translucent material.

In addition, the intervals of the plurality of grooves formed in wavelength dispersion element 142 are not particularly limited. The intervals are only needed to be arbitrarily formed so that laser beam 310 has a desired wavelength.

Presser 143 is a member that fixes wavelength dispersion element 142 to pedestal 141 by pressing on wavelength dispersion element 142 against pedestal 141. Presser 143 presses on wavelength dispersion element 142 in a direction perpendicular to the surface on which wavelength dispersion element 142 is provided (that is, main surface 142a in which a plurality of grooves are formed) (which is also referred to as the normal direction of main surface 142a or the thickness direction of wavelength dispersion element 142 in the present embodiment). More specifically, presser 143 presses on wavelength dispersion element 142 in the thickness direction of wavelength dispersion element 142. Accordingly, presser 143 fixes wavelength dispersion element 142 to pedestal 141. Presser 143 is, for example, an elongated plate spring, one end of which is fixed to pedestal 141 and the other end of which presses on wavelength dispersion element 142. In the present embodiment, pressers 143 press back surface 142b of wavelength dispersion element 142.

Here, when viewed from the front (when viewed from the normal direction of main surface 142a), pressers 143 fix wavelength dispersion element 142 to pedestal 141 by pressing on wavelength dispersion element 142 in the thickness direction of wavelength dispersion element 142 at positions symmetric with respect to the center of light spot 300 formed by superimposing the light beam emitted from each of the plurality of semiconductor light emitting elements 121 on main surface 142a. In the present embodiment, pressers 143 press wavelength dispersion element 142 from two locations, upper and lower, which are symmetric with respect to light spot 300, that is, at upper and lower positions which are symmetric with respect to light spot 300 on the line where (i) the surface which passes through light spot 300 and is orthogonal to the extending direction of the grooves formed on main surface 142a and (ii) back surface 142b intersect. In the present embodiment, light spot 300 is located in the central portion (substantially at the center) of wavelength dispersion element 142 when viewed from the front or the back. For that reason, pressers 143 fix wavelength dispersion element 142 to pedestal 141 by pressing on wavelength dispersion element 142 in the thickness direction of wavelength dispersion element 142 at positions which are symmetric with respect to the central portion of wavelength dispersion element 142 when viewed from the front or the back.

Presser 143 is elongated in a direction orthogonal to the elongated direction of wavelength dispersion element 142 when wavelength dispersion element 142 is viewed from the back (when viewed from the side from which wavelength dispersion element 142 emits the light beam from semiconductor element unit 120). One end of presser 143 is fixed to pedestal 141 by adjusting screw 212, and the other end is formed with convex portion 145 protruding from the surface of the flat plate-shaped presser 143 toward wavelength dispersion element 142. Wavelength dispersion element 142 is pressed and fixed to pedestal 141 by being pressed by convex portion 145.

In addition, for example, presser 143 presses on wavelength dispersion element 142 from back surface 142b on the back side of main surface 142a toward pedestal 141. Accordingly, main surface 142a abuts against pedestal 141 (more specifically, abutting portion 220 of pedestal 141).

In addition, groove portions 147 are formed on pedestal 141. Adjusting screws 212 are fitted in groove portions 147 and fixed to pedestal 141.

In addition, a coil spring (not shown) may be disposed in groove portion 147 so as to surround the circumference of adjusting screw 212. Presser 143 may be supported so as not to come off from pedestal 141 by being sandwiched between adjusting screw 212 and the coil spring.

In the present embodiment, pedestal 141 is formed with two groove portions 147. For example, adjusting screw 212 and a coil spring (not shown) are disposed in each of two groove portions 147. Adjusting screw 212 and the coil spring disposed in each of two groove portions 147 support presser 143, respectively. Wavelength dispersion element 142 is pressed from above by convex portions 145 of two pressers 143 and fixed to pedestal 141. By adjusting the degree of fastening of adjusting screw 212, the pressing force of presser 143 fixed to adjusting screw 212 on wavelength dispersion element 142 is adjusted.

In this way, multiplexer 140 included in semiconductor laser device 100 fixes wavelength dispersion element 142 by pressing on wavelength dispersion element 142 from back surface 142b at both ends of wavelength dispersion element 142 in the vertical direction toward pedestal 141 side by the plate springs (pressers 143). In addition, multiplexer 140 has a configuration in which the pressing force on wavelength dispersion element 142 can be changed by rotating the adjusting screw (adjusting screw 212) that supports the other end of the plate spring.

### <Semiconductor Element Unit>

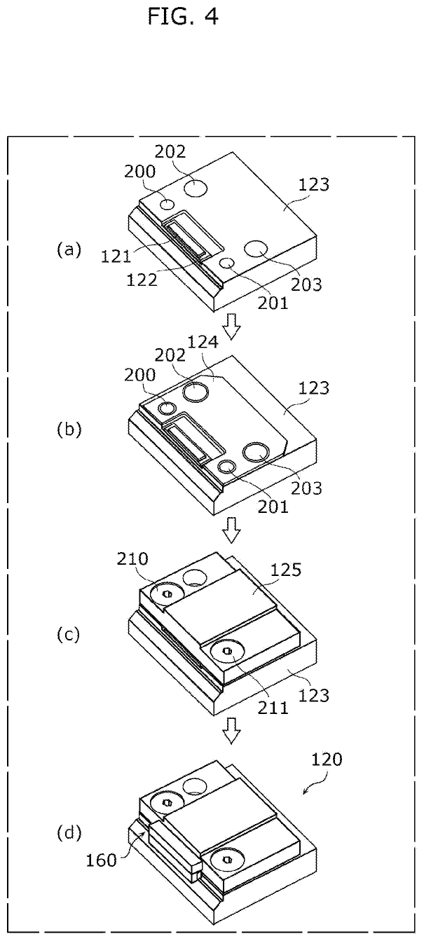

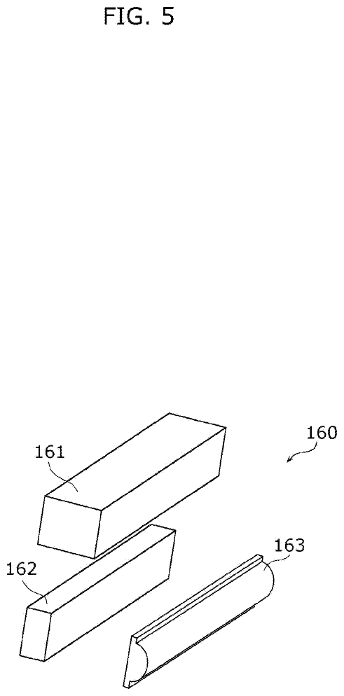

Subsequently, the configuration of semiconductor element unit 120 will be described in detail with reference to FIG. 4 and FIG. 5.

FIG. 4 is a perspective view showing a manufacturing process of semiconductor element unit 120.

As shown in (a) in FIG. 4, first, semiconductor light emitting element 121, sub-mount 122, and first base block 123 are prepared.

Semiconductor light emitting element 121 is a light source that emits a light beam in semiconductor element unit 120. In addition, the resonance of light beams is generated between partially reflecting mirror 150 and semiconductor light emitting element 121.

In the present embodiment, semiconductor light emitting element 121 includes one light emitting point and emits light from one location.

In addition, the material adopted for semiconductor light emitting element 121 is not particularly limited.

Semiconductor light emitting element 121 is mounted on sub-mount 122.

Sub-mount 122 is a member on which semiconductor light emitting element 121 is mounted and is mounted on first base block 123.

Sub-mount 122 plays a role of enhancing the heat dissipation of semiconductor light emitting element 121. In addition, sub-mount 122 suppresses the destruction of semiconductor light emitting element 121 due to the difference in the coefficient of thermal expansion between semiconductor light emitting element 121 and first base block 123.

The material adopted for sub-mount 122 is not particularly limited. The material adopted for sub-mount 122 is, for example, a ceramic material or the like.

First base block 123 is a block on which sub-mount 122 on which semiconductor light emitting element 121 is mounted is mounted. First base block 123 is mounted on main surface 111 of base 110.

First base block 123 is formed on the upper surface with holes 200, 201, 202, and 203 into which screws for fixing second base block 125, which will be described later, to first base block 123 are fitted.

Next, as shown in (b) in FIG. 4, insulating sheet 124 is disposed on the upper surface of the first base block.

Insulating sheet 124 is a sheet that electrically insulates first base block 123 and second base block 125 when second base block 125 is disposed above first base block 123.

Insulating sheet 124 is only needed to have any electrical insulating property, and any material may be used.

In addition, insulating sheet 124 is formed with through holes in accordance with the positions of holes 200, 201, 202, and 203.

Next, as shown in (c) in FIG. 4, second base block 125 is disposed above first base block 123. Specifically, second base block 125 is disposed above first base block 123 via insulating sheet 124 so as to sandwich insulating sheet 124 together with first base block 123.

Second base block 125 is a block which is placed above first base block 123 via insulating sheet 124. Through holes are formed in second base block 125 in accordance with the positions of holes 200, 201, 202, and 203. For example, screws 210 and 211 are arranged in the through holes. First base block 123 and second base block 125 are fixed by screws 210 and 211.

First base block 123 and second base block 125 is formed from, for example, a metal material, a ceramic material, or the like.

Next, as shown in (d) in FIG. 4, optical unit 160 is fixed to the side surface of second base block 125.

### <Optical Unit>

Optical unit 160 is an optical system that controls the light distribution of the light emitted from semiconductor light emitting element 121. Optical unit 160 is disposed at a position in semiconductor element unit 120 where the light emitted by semiconductor light emitting element 121 is irradiated.

FIG. 5 is an exploded perspective view showing optical unit 160.

Optical unit 160 includes optical holder 161, 90 degree image rotation optical system 162, and fast axis collimator lens 163.

Optical holder 161 is a member for fixing 90 degree image rotation optical system 162 and fast axis collimator lens 163 to the light emitting side of semiconductor light emitting element 121. In the present embodiment, a part of optical holder 161 is fixed to second base block 125, and another part thereof is fixed to 90 degree image rotation optical system 162.

The material adopted for optical holder 161 is, for example, glass, metal material, or the like.

### Effects, Etc.

As described above, semiconductor laser device 100 according to Embodiment 1 includes: a plurality of semiconductor light emitting elements 121 each of which emits a light beam; wavelength dispersion element 142 that emits the light beam emitted from each of the plurality of semiconductor light emitting elements 121 to pass through one optical path; pedestal 141 that supports wavelength dispersion element 142; and presser 143 that fixes wavelength dispersion element 142 to pedestal 141 by pressing on wavelength dispersion element 142. Presser 143 presses on wavelength dispersion element 142 in a direction perpendicular to a surface on which wavelength dispersion element 142 is provided. That is, presser 143 presses on wavelength dispersion element 142 in the thickness direction of wavelength dispersion element 142.

In the present embodiment, semiconductor laser device 100 includes: three semiconductor light emitting elements 121 each of which emits a light beam; three fast axis collimator lenses 163 each of which collimates the light beam in the fast axis direction emitted from a corresponding one of the three semiconductor light emitting elements 121 and emits the light beam; wavelength dispersion element 142 which transmits a plurality of light beams emitted from each of the three fast axis collimator lenses 163 and emits the plurality of light beams so that the plurality of light beams pass through one optical path; and external resonator 400 including partially reflecting mirror 150 that transmits one part and reflects the other part of the light beams emitted from wavelength dispersion element 142.

Wavelength dispersion element 142 needs to be provided with grooves formed with high accuracy in size and shape in order to multiplex a plurality of light beams. Here, the grooves provided in wavelength dispersion element 142 may be distorted from a desired shape due to a manufacturing error, heat generation due to irradiation with light, or the like. Therefore, in semiconductor laser device 100, presser 143 fixes wavelength dispersion element 142 by pressing on wavelength dispersion element 142. According to this, presser 143 can appropriately distort wavelength dispersion element 142 by pressing on an appropriate position. In other words, by presser 143 pressing on an appropriate position of wavelength dispersion element 142, wavelength dispersion element 142 distorted into an unintended shape can be made into a desired shape. Alternatively, by presser 143 pressing on an appropriate position of wavelength dispersion element 142, it is possible to support wavelength dispersion element 142 which may be distorted into an unintended shape due to heat or the like so as to maintain a desired shape. Accordingly, according to semiconductor laser device 100, for example, when semiconductor laser device 100 is adopted as a light source that resonates externally, the influence of wavelength dispersion element 142 on the multiplexing of a plurality of light beams can be suppressed, so that it is possible to suppress the occurrence of unintended resonance between semiconductor laser device 100 and the resonator.

In addition, for example, when viewed from the thickness direction of wavelength dispersion element 142, pressers 143 press wavelength dispersion element 142 in the thickness direction of wavelength dispersion element 142 at positions symmetric with respect to the center of light spot 300 formed by superimposing the light emitted from each of the plurality of semiconductor emitting elements 121 on main surface 142 of wavelength dispersion element 142.

According to such a configuration, presser 143 presses on wavelength dispersion element 142 at positions symmetric with respect to the center of light spot 300. For that reason, even when wavelength dispersion element 142 (more specifically, the shape of the grooves formed on main surface 142a of wavelength dispersion element 142) is slightly distorted by presser 143, that is, even when the intervals of the plurality of grooves formed on main surface 142a of wavelength dispersion element 142 are deviated from desired intervals, the intervals of the plurality of grooves are deviated symmetrically with respect to light spot 300. For that reason, according to such a configuration, it is possible to suppress the influence on multiplexing the plurality of light beams, as compared with the case where the intervals of the plurality of grooves are asymmetrically shifted with respect to light spot 300. Accordingly, according to semiconductor laser device 100, the occurrence of unintended resonance can be further suppressed.

In addition, for example, presser 143 presses on wavelength dispersion element 142 from back surface 142b on the back side of main surface 142a toward pedestal 141.

According to such a configuration, main surface 142a of wavelength dispersion element 142 is pressed against pedestal 141 (more specifically, contact portion 220) by presser 143. For that reason, the heat generated by irradiating main surface 142a with light easily escapes from main surface 142a of wavelength dispersion element 142 to pedestal 141. For that reason, wavelength dispersion element 142 is less likely to be deteriorated by heat.

In addition, for example, presser 143 is an elongated plate spring, one end of which is fixed to pedestal 141 and the other end of which presses on wavelength dispersion element 142.

According to such a configuration, wavelength dispersion element 142 can be pressed by presser 143 with an appropriate pressing force with a simple configuration. In addition, for example, when presser 143 is a plate spring, by adjusting the degree of fastening of adjusting screw 212 for fixing the other end of the plate spring to pedestal 141, the pressing force of presser 143 on wavelength dispersion element 142 can be adjusted with a simple configuration.

In addition, for example, semiconductor laser device 100 (more specifically, external resonator 400) further includes coupling optical system 130 that is disposed between a plurality of semiconductor emitting elements 121 and wavelength dispersion element 142, and superimposes the light beam emitted from each of the plurality of semiconductor emitting elements 121 on wavelength dispersion element 142. In the present embodiment, coupling optical system 130 superimposes a plurality of light beams emitted from fast axis collimator lenses 163 between fast axis collimator lenses 163 and wavelength dispersion element 142 so as to form one light spot 300 by wavelength dispersion element 142.

According to such a configuration, for example, the light beam emitted from each of the plurality of semiconductor light emitting elements 121 can be collected by coupling optical system 130, so that even if the distance between the plurality of semiconductor light emitting elements 121 and wavelength dispersion element 142 is reduced, the light emitted from each of the plurality of semiconductor light emitting elements 121 can easily be converted into one light spot 300 by wavelength dispersion element 142. For that reason, according to such a configuration, semiconductor laser device 100 can be miniaturized.

In addition, for example, semiconductor laser device 100 (more specifically, external resonator 400) further includes fast axis collimator lens 163 that collimates the light beam in the fast axis direction emitted from each of the plurality of semiconductor light emitting elements 121, respectively. In the present embodiment, semiconductor laser device 100 includes three fast axis collimator lenses 163 so as to have a one-to-one correspondence with each of three semiconductor light emitting elements 121.

The light in the fast axis direction has a larger radiation angle (spread angle) than the light in the slow axis direction. For that reason, by providing fast axis collimator lens 163, it is possible to suppress the spread of the light emitted from semiconductor light emitting element 121. Accordingly, the distance between wavelength dispersion element 142 and semiconductor light emitting element 121 can be widened. For that reason, the positions where wavelength dispersion element 142 and semiconductor light emitting element 121 are disposed can be made freer.

### [Variations]

Subsequently, variations of Embodiment 1 will be described. It should be noted that in the variations of Embodiment 1 described below, the configuration other than the multiplexer are the same as the configuration of semiconductor laser device 100 according to Embodiment 1. It should be noted that the variations described below have the same configuration as that of semiconductor laser device 100 according to Embodiment 1 except for the multiplexer. In the variations described below, the same configurations as those of semiconductor laser device 100 may be designated by the same reference numerals, and the description may be partially simplified or omitted.

### <Variation 1>

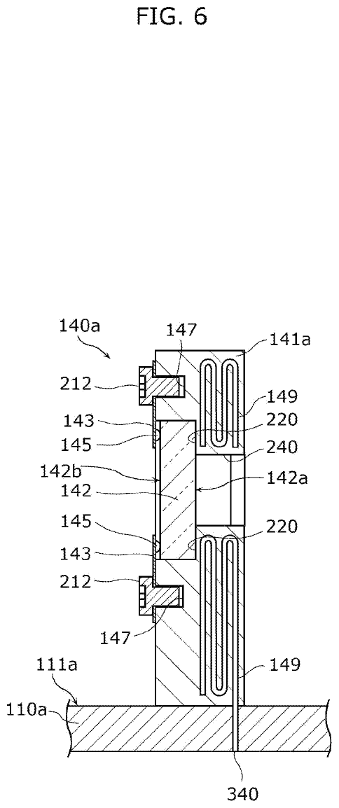

FIG. 6 is a cross-sectional view showing multiplexer 140a according to Variation 1 of Embodiment 1. It should be noted that the cross section shown in FIG. 6 is a cross section corresponding to the cross section shown in FIG. 3D.

Multiplexer 140a includes flow path 149. More specifically, pedestal 141a included in multiplexer 140a has flow path 149 inside.

Flow path 149 is a through hole formed in pedestal 141a. It should be noted that although not shown, respective flow paths 149 formed in the upper part and the lower part of pedestal 141a are provided in communication with each other.

In addition, flow path 149 penetrates the inside of base 110a from main surface 111a of base 110a on which multiplexer 140a is disposed, and communicates with hole 340 provided in the lower part of base 110a. For example, a cooling liquid or gas is introduced into flow path 149 from hole 340, whereby pedestal 141 is cooled. For that reason, wavelength dispersion element 142 is cooled. For that reason, wavelength dispersion element 142 is less likely to undergo deterioration such as deformation due to heat.

It should be noted that although not shown, both ends of flow path 149 penetrate base 110a. Accordingly, for example, the cooling liquid and gas flowing in from hole 340 communicating with flow path 149 pass through flow path 149 and flow out from the hole (not shown) which is the other end of flow path 149.

In addition, the cooling liquid and gas may be arbitrary. The cooling liquid and gas may be, for example, water or air.

In addition, flow path 149 does not have to penetrate base 110. For example, flow path 149 may be connected to a hole provided in the upper part of pedestal 141a. The cooling liquid or gas may flow in through the hole.

### <Variation 2>

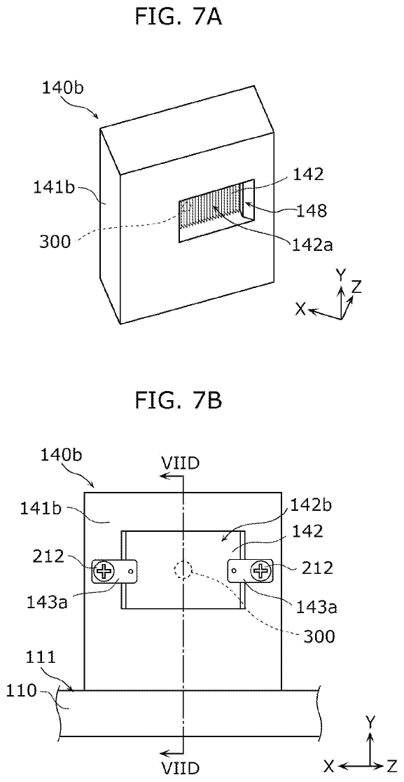

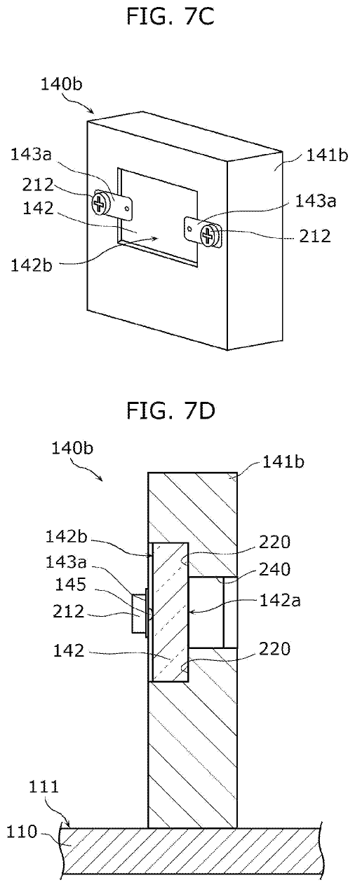

FIG. 7A is a perspective view showing a main surface 142a side of wavelength dispersion element 142 included in multiplexer 140b according to Variation 2 of Embodiment 1. FIG. 7B is a rear view showing multiplexer 140b according to Variation 2 of Embodiment 1. FIG. 7C is a perspective view showing a back surface 142b side of wavelength dispersion element 142 included in multiplexer 140b according to Variation 2 of Embodiment 1. FIG. 7D is a cross-sectional view showing multiplexer 140b according to Variation 2 of Embodiment 1 in the VIID-VIID line of FIG. 7B.

Presser 143a included in multiplexer 140b fixes wavelength dispersion element 142 to pedestal 141b by pressing on wavelength dispersion element 142 against pedestal 141b. Specifically, presser 143a fixes wavelength dispersion element 142 to pedestal 141 by pressing on wavelength dispersion element 142 in the thickness direction of wavelength dispersion element 142. In the present embodiment, pressers 143a fix wavelength dispersion element 142 to pedestal 141a by pressing on wavelength dispersion element 142 from back surface 142b to pedestal 141.

Pressers 143a fix wavelength dispersion element 142 to pedestal 141 by pressing on wavelength dispersion element 142 in the thickness direction of wavelength dispersion element 142 at positions symmetric with respect to the center of light spot 300 formed by superimposing the light emitted from each of the plurality of semiconductor light emitting elements 121 on main surface 142a when viewed from the front (when viewed from the normal direction of main surface 142a).

Here, in the present variation, pressers 143a press wavelength dispersion element 142 from two locations in the left-right direction (direction parallel to the XZ plane) which are symmetric with respect to light spot 300 when viewed from the front or the back. In the present variation, light spot 300 is located in the central portion (substantially at the center) of wavelength dispersion element 142 when viewed from the front or the back. For that reason, pressers 143a fix wavelength dispersion element 142 to pedestal 141 by pressing on wavelength dispersion element 142 in the thickness direction of wavelength dispersion element 142 at positions symmetric (line-symmetric or rotationally symmetric) with respect to the central portion of wavelength dispersion element 142 when viewed from the front or the back.

Presser 143a is elongated in a direction parallel to the elongated direction of wavelength dispersion element 142 when wavelength dispersion element 142 is viewed from the back. One end of presser 143 is fixed to pedestal 141a by adjusting screw 212, and the other end is formed with convex portion 145 protruding from the surface of the flat plate-shaped presser 143a toward wavelength dispersion element 142. Wavelength dispersion element 142 is pressed and fixed to pedestal 141b by being pressed by convex portion 145.

It should be noted that as with pedestal 141, one end of presser 143a is fixed to pedestal 141a by adjusting screw 212 that fits into a groove portion (not shown) provided on pedestal 141a.

### <Variation 3>

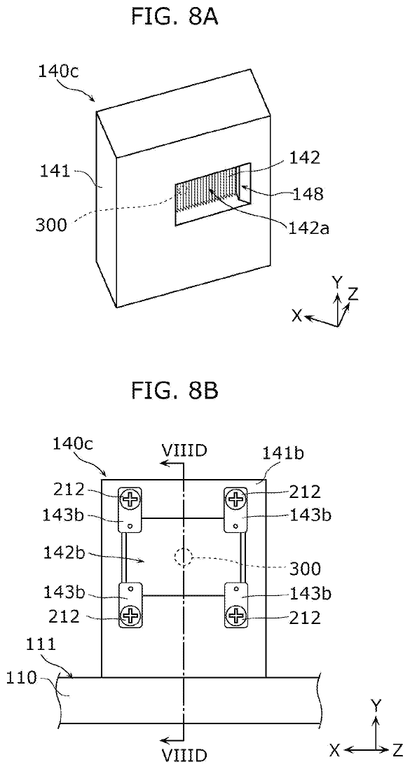

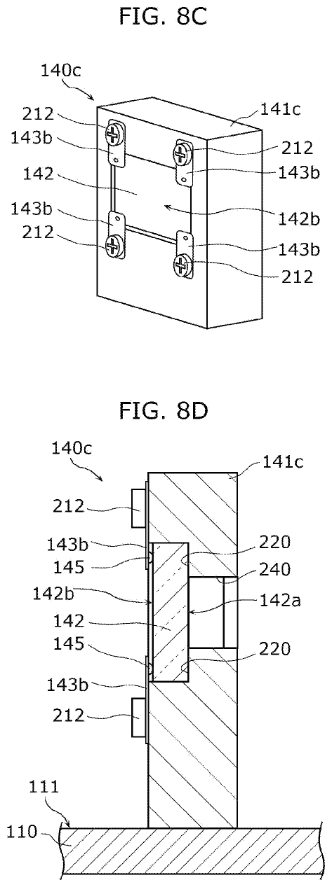

FIG. 8A is a perspective view showing main surface 142a side of wavelength dispersion element 142 included in multiplexer 140c according to Variation 3 of Embodiment 1. FIG. 8B is a rear view showing multiplexer 140b according to Variation 3 of Embodiment 1. FIG. 8C is a perspective view showing a back surface 142b side of wavelength dispersion element 142 included in multiplexer 140c according to Variation 3 of Embodiment 1. FIG. 8D is a cross-sectional view showing multiplexer 140c according to Variation 3 of Embodiment 1 in the VIIID-VIIID line of FIG. 8B.

Pressers 143b included in multiplexer 140c fix wavelength dispersion element 142 to pedestal 141c by pressing on wavelength dispersion element 142 against pedestal 141c. Specifically, pressers 143b fix wavelength dispersion element 142 to pedestal 141c by pressing on wavelength dispersion element 142 in the thickness direction of wavelength dispersion element 142. In the present embodiment, pressers 143a fix wavelength dispersion element 142 to pedestal 141 by pressing on wavelength dispersion element 142 from back surface 142b to pedestal 141.

Pressers 143b fix wavelength dispersion element 142 to pedestal 141 by pressing on wavelength dispersion element 142 in the thickness direction of wavelength dispersion element 142 at positions symmetric with respect to the center of light spot 300 formed by superimposing the light emitted from each of the plurality of semiconductor light emitting elements 121 on main surface 142a when viewed from the front (when viewed from the normal direction of main surface 142a).

Here, in the present variation, pressers 143b press wavelength dispersion element 142 from four corners of wavelength dispersion element 142 which are symmetric with respect to light spot 300 when viewed from the front or the back. In the present variation, light spot 300 is located in the central portion (substantially at the center) of wavelength dispersion element 142 when viewed from the front or the back. For that reason, pressers 143b fix wavelength dispersion element 142 to pedestal 141 by pressing on wavelength dispersion element 142 in the thickness direction of wavelength dispersion element 142 at positions symmetric (twice rotationally symmetric) with respect to the central portion of wavelength dispersion element 142 when viewed from the front or the back.

One end of presser 143b is fixed to pedestal 141 by adjusting screw 212, and the other end is formed with convex portion 145 protruding from the surface of the flat plate-shaped presser 143b toward wavelength dispersion element 142. Wavelength dispersion element 142 is pressed and fixed to pedestal 141c by being pressed by convex portion 145.

It should be noted that as with pedestal 141, one end of presser 143b is fixed to pedestal 141c by adjusting screw 212 that fits into a groove portion (not shown) provided on pedestal 141c.

As shown in Variation 2 and Variation 3, the positions where pressers 143 press wavelength dispersion element 142 may be positions symmetric with respect to light spot 300.

It should be noted that symmetric with respect to light spot 300 means symmetric with respect to the center of light spot 300 when viewed from the normal direction of main surface 142a in which a plurality of grooves are formed. For example, symmetric with respect to light spot 300 may be symmetric with respect to a line which passes through the center of light spot 300 and extends in a direction parallel to the direction in which the plurality of grooves extend when viewed from the normal direction of main surface 142a in which a plurality of grooves are formed. In addition, for example, symmetric with respect to light spot 300 may be symmetric with respect to a line which passes through the center of light spot 300 and extends in a direction parallel to the direction in which the plurality of grooves extend when viewed from the normal direction of main surface 142a in which a plurality of grooves are formed. For example, symmetric with respect to light spot 300 may be n-fold rotationally symmetric (n is a positive even number) when viewed from the normal direction of main surface 142a on which a plurality of grooves are formed.

### Embodiment 2

Subsequently, the semiconductor laser device according to Embodiment 2 will be described. It should be noted that in Embodiment 2 described below, the configuration other than the multiplexer are the same as the configuration of semiconductor laser device 100 according to Embodiment 1. In Embodiment 2 described below, the same configurations as those of semiconductor laser device 100 may be designated by the same reference numerals, and the description may be partially simplified or omitted.

### [Configuration]

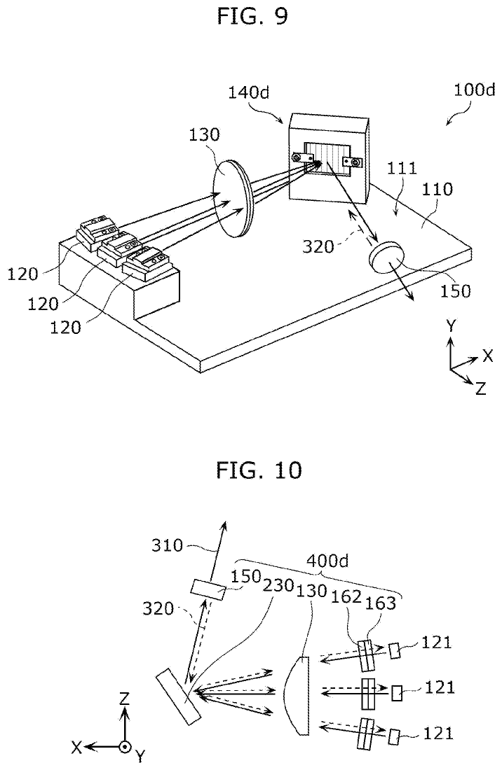

FIG. 9 is a perspective view showing semiconductor laser device 100d according to Embodiment 2. FIG. 10 is a schematic diagram for explaining the resonance of light in semiconductor laser device 100d according to Embodiment 2.

Semiconductor laser device 100d includes base 110, a plurality of semiconductor element units 120, coupling optical system 130, multiplexer 140d, and partially reflecting mirror 150. External resonator 400d included in semiconductor laser device 100d according to Embodiment 2 includes fast axis collimator lens 163, 90 degree image rotation optical system 162, coupling optical system 130, partially reflecting mirror 150, and wavelength dispersion element 142 included in multiplexer 140d. Semiconductor laser device 100d according to Embodiment 2 has a different configuration of multiplexer 140d from semiconductor laser device 100 according to Embodiment 1.

Wavelength dispersion element 142 included in multiplexer 140 according to Embodiment 1 is a so-called transmissive type that transmits light. The wavelength dispersion element (diffraction grating) 230 included in multiplexer 140d according to Embodiment 2 is a so-called reflection type that reflects light.

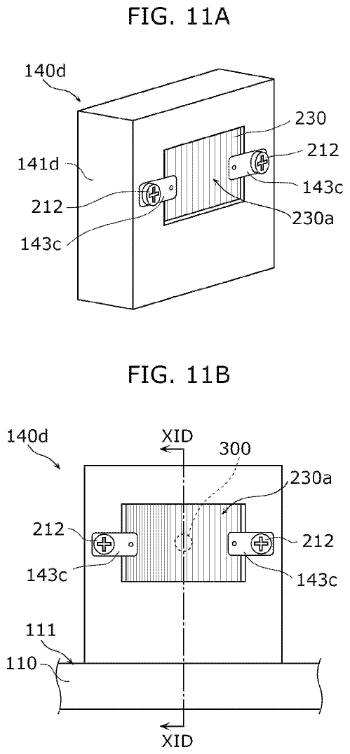

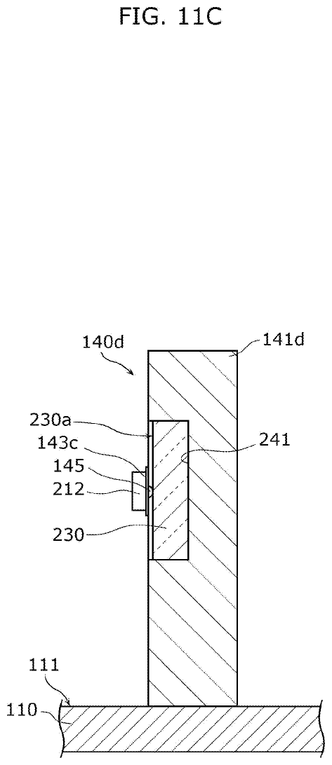

FIG. 11A is a perspective view showing a main surface 230a side of multiplexer 140d included in semiconductor laser device 100d according to Embodiment 2. FIG. 11B is a front view showing multiplexer 140d included in semiconductor laser device 100d according to Embodiment 2. FIG. 11C is a cross-sectional view showing multiplexer 140d included in semiconductor laser device 100d according to Embodiment 2 in the XID-XID line of FIG. 11B.

Multiplexer 140d includes pedestal 141d, wavelength dispersion element 230, presser 143c, and adjusting screw 212.

Pedestal 141d is a table on which wavelength dispersion element 230 is mounted. In the present embodiment, pedestal 141d is formed with recess 241 recessed in the thickness direction. Wavelength dispersion element 142 is disposed in recess 241.

Wavelength dispersion element 230 has a plate shape, and is a diffraction grating (optical element) in which a plurality of irregularities extending in the first direction are formed on main surface 230a of wavelength dispersion element 230, in other words, a plurality of grooves extending in the first direction are formed. In the present embodiment, wavelength dispersion element 230 has light reflectivity. For example, a reflective film such as silver or aluminum having light reflectivity is formed on the surface of a plurality of grooves formed on wavelength dispersion element 230. The reflective film is formed on main surface 230a, for example, so as to follow the uneven shape formed on main surface 230a. Alternatively, wavelength dispersion element 230 may be formed of a material having light reflectivity.

The material used for wavelength dispersion element 230 or the reflective film formed on wavelength dispersion element 230 is only needed to have light reflectivity, and is not particularly limited. The material used for wavelength dispersion element 230 or the reflective film formed on wavelength dispersion element 230 is, for example, silver, aluminum, or the like.

Presser 143c is a member that fixes wavelength dispersion element 230 to pedestal 141d by pressing on wavelength dispersion element 230 against pedestal 141d. Presser 143c is, for example, an elongated plate spring, one end of which is fixed to pedestal 141d and the other end of which presses on wavelength dispersion element 230. In the present embodiment, pressers 143c press wavelength dispersion element 230 from main surface 230a of wavelength dispersion element 230 toward pedestal 141d.

According to such a configuration, for example, if presser 143c is formed of a material having high thermal conductivity such as metal, the heat generated by the irradiation of light on main surface 230a easily escapes from main surface 230a of wavelength dispersion element 230 to presser 143c. For that reason, wavelength dispersion element 230 is less likely to be deteriorated by heat.

### [Variation]

Subsequently, a variation of Embodiment 2 will be described. It should be noted that in the variation described below, the configuration other than the multiplexer is the same as the configuration of semiconductor laser device 100d according to Embodiment 2. In the variation described below, the same reference numerals may be given to the configurations substantially the same as those of semiconductor laser device 100d, and the description may be partially simplified or omitted.

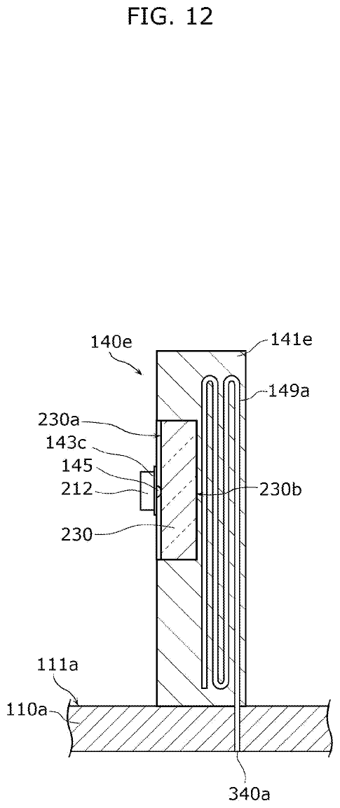

FIG. 12 is a cross-sectional view showing multiplexer 140e according to a variation of Embodiment 2. It should be noted that the cross section shown in FIG. 12 is a cross section corresponding to the cross section shown in FIG. 11C.

Multiplexer 140e includes flow path 149a. More specifically, pedestal 141e included in multiplexer 140e has flow path 149a inside.

Flow path 149a is a through hole formed in pedestal 141e.

In addition, flow path 149a penetrates base 110a, and communicates with hole 340a provided in the lower part of base 110a. For example, a cooling liquid or gas is introduced into flow path 149a from hole 340a, whereby pedestal 141e is cooled. For that reason, wavelength dispersion element 230 is cooled. For that reason, wavelength dispersion element 230 is less likely to undergo deterioration such as deformation due to heat.

Although not shown, both ends of flow path 149a penetrate base 110a. Accordingly, for example, the cooling liquid and gas flowing in from hole 340a communicating with one end of flow path 149a pass through flow path 149a and flow out from the hole (not shown) which is the other end of flow path 149a.

### Embodiment 3

Subsequently, the semiconductor laser device according to Embodiment 3 will be described. It should be noted that in the description of the semiconductor laser device according to Embodiment 3, the differences from the semiconductor laser device according to Embodiment 1 will be mainly described. In the description of the semiconductor laser device according to Embodiment 3, the same reference numerals may be given to the same configurations as those of the semiconductor laser device according to Embodiment 1, and the description may be partially omitted or simplified.

### [Configuration]

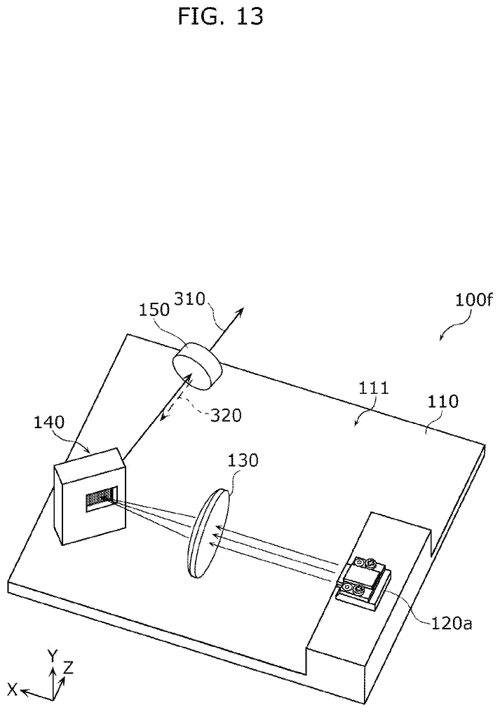

FIG. 13 is a perspective view showing semiconductor laser device 100f according to Embodiment 3.

Semiconductor laser device 100f includes base 110, one semiconductor element unit 120a, coupling optical system 130, multiplexer 140, and partially reflecting mirror 150. Semiconductor laser device 100f according to Embodiment 3 has a different configuration of semiconductor element unit 120a from semiconductor laser device 100 according to Embodiment 1.

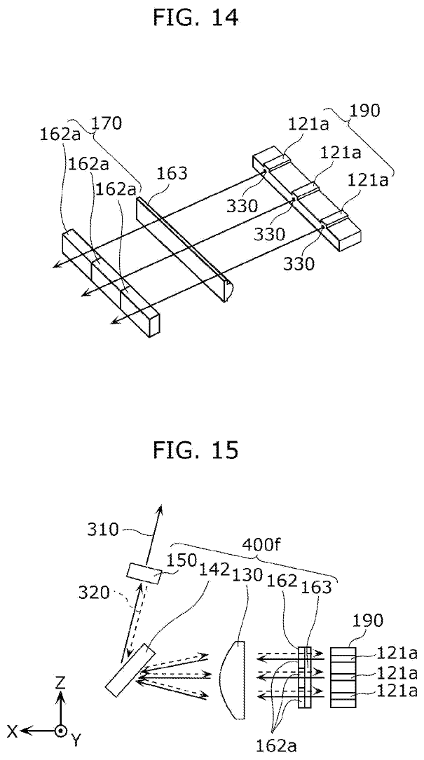

FIG. 14 is a perspective view showing amplifier 121a included in semiconductor laser device 100f according to Embodiment 3. It should be noted that in FIG. 14, a plurality of amplifiers 121a (semiconductor light emitting element array 190), fast axis collimator lens 163, and a plurality of 90 degree image rotation optical systems 162a (90 degree image rotation optical system array 170) among the components included in semiconductor element unit 120a are shown, and illustration is omitted for other components. In addition, in FIG. 14, fast axis collimator lens 163 and 90 degree image rotation optical system array 170 are disposed apart from each other, but they may be in contact with each other. FIG. 15 is a schematic diagram for explaining the resonance of light beams in semiconductor laser device 100f according to Embodiment 3.

In semiconductor element unit 120a, semiconductor light emitting element 121 of semiconductor element unit 120 according to Embodiment 1 is replaced with semiconductor light emitting element array 190, and 90 degree image rotation optical system 162 is replaced with 90 degree image rotation optical system array 170. Other components have the same configuration, for example, as semiconductor element unit 120 shown in FIG. 4.

Semiconductor light emitting element array 190 is a semiconductor light emitting element including a plurality of amplifiers 121a. Semiconductor light emitting element array 190 emits a light beam from each of the plurality of amplifiers 121a toward fast axis collimator lens 163. In other words, semiconductor light emitting element array 190 emits a plurality of light beams toward fast axis collimator lens 163.

In this way, the semiconductor laser device according to the present disclosure is only needed to be provided with a plurality of amplifiers that emit light beams, and for example, a plurality of amplifiers may be realized by the plurality of semiconductor light emitting elements 121 as shown in FIG. 2, or a plurality of amplifiers 121a may be realized by semiconductor light emitting element array 190 as shown in FIG. 14. In addition, the semiconductor laser device according to the present disclosure is only needed to have one or more fast axis collimator lenses 163, and may be provided with one fast axis collimator lens 163 for one amplifier, or may be provided with one fast axis collimator lens for a plurality of amplifiers.

90 degree image rotation optical system array 170 is an array lens including a plurality of 90 degree image rotation optical systems 162a. Specifically, 90 degree image rotation optical system array 170 includes the same number of 90 degree image rotation optical systems 162a as amplifiers 121a.

90 degree image rotation optical system array 170 is arranged between fast axis collimator lens 163 and wavelength dispersion element 142, similarly to 90 degree image rotation optical system 162 shown in FIG. 2.

Here, 90 degree image rotation optical system array 170 includes a plurality of 90 degree image rotation optical systems 162a at the same intervals as the plurality of amplifiers 121a. In other words, 90 degree image rotation optical system array 170 includes a plurality of 90 degree image rotation optical systems 162a at intervals equal to light emitting points 330 of the plurality of amplifiers 121a. That is, as shown in FIG. 15, external resonator 400f includes 90 degree image-rotating optical system array 170 including a plurality of 90 degree image-rotating optical systems 162a that interchange the fast-axis direction and the slow-axis direction of the light beam emitted from fast axis collimator lens 163 arranged between fast axis collimator lens 163 and wavelength dispersion element 142 at the same intervals as the plurality of amplifiers 121a. Here, for example, the intervals of the plurality of 90 degree image rotation optical systems 162a are the distances between the centers of the plurality of 90 degree image rotation optical systems 162a. Here, the center is, for example, the center in the top view of 90 degree image rotation optical system 162a, or the center of 90 degree image rotation optical system 162a when 90 degree image rotation optical system array 170 is viewed from the normal direction of the light emitting surface of 90 degree image rotation optical system array 170.

### Effects, Etc.

As described above, semiconductor laser device 100f according to Embodiment 3 includes, for example, in the configuration of semiconductor laser device 100, semiconductor light emitting element array 190 including a plurality of amplifiers 121a instead of the plurality of semiconductor light emitting elements 121.

According to such a configuration, the relative positions of the plurality of amplifiers 121a do not change as compared with the case where the positions of the plurality of semiconductor light emitting elements 121 are adjusted (optically adjusted), so that the optical adjustment becomes simple.

In addition, for example, semiconductor laser device 100f (more specifically, external resonator 400f) according to Embodiment 3 further includes 90 degree image rotation optical system array 170 including a plurality of 90 degree image rotation optical systems 162a at the same intervals as a plurality of amplifiers 121a between fast axis collimator lens 163 and wavelength dispersion element 142.

Light beams parallel to each other are emitted from the plurality of amplifiers 121a. In addition, 90 degree image rotation optical system array 170 includes a plurality of 90 degree image rotation optical systems 162a arranged at intervals equal to intervals of the plurality of amplifiers 121a. In addition, each of the plurality of 90 degree image rotation optical systems 162a interchanges the fast axis direction and a slow axis direction of the light beam emitted from fast axis collimator lens 163. Accordingly, the respective light beams emitted from the plurality of amplifiers 121a can be caused to be incident on respective 90 degree image rotation optical systems 162a.

### Other Embodiments

The semiconductor laser devices according to the embodiments of the present disclosure have been described above based on the respective embodiments, but the present disclosure is not limited to these embodiments.

For example, it is described in the above embodiments that the surface of the wavelength dispersion element on the side where the light beam from the amplifier is incident is the main surface, and a plurality of grooves are formed on the main surface. For example, the surface, in the wavelength dispersion element, on the back side of the surface on which the light beam from the amplifier is incident may be the main surface.

In addition, forms obtained by applying various modifications to each embodiment conceived by a person skilled in the art or forms realized by arbitrarily combining the components in the different embodiments without departing from the spirit of the present disclosure are also included in the scope of one or more aspects.

### INDUSTRIAL APPLICABILITY

The semiconductor laser device of the present disclosure is used, for example, as a light source of a processing device used for laser processing.

1. A semiconductor laser device comprising:
a plurality of amplifiers each of which emits a light beam;
a diffraction grating that guides the light beam emitted from each of the plurality of amplifiers to pass through one optical path;
a pedestal that supports the diffraction grating; and
a presser that fixes the diffraction grating to the pedestal by pressing on the diffraction grating,
wherein the presser presses on the diffraction grating in a direction perpendicular to a surface on which the diffraction grating is provided.

2. The semiconductor laser device according to claim 1,
wherein the presser presses on the diffraction grating in a thickness direction of the diffraction grating at positions symmetric with respect to a center of a light spot formed by superimposing the light beam emitted from each of the plurality of amplifiers on a main surface of the diffraction grating when viewed from the thickness direction of the diffraction grating.

3. The semiconductor laser device according to claim 2,
wherein the presser presses on the diffraction grating from the main surface toward the pedestal.

4. The semiconductor laser device according to claim 2,
wherein the presser presses on the diffraction grating from a back surface on a back side of the main surface toward the pedestal.

5. The semiconductor laser device according to claim 1,
wherein the presser is an elongated plate spring, one end of which is fixed to the pedestal and an other end of which presses on the diffraction grating.

6. The semiconductor laser device according to claim 1,
wherein the pedestal has a flow path inside the pedestal.

7. The semiconductor laser device according to claim 1, further comprising:
a coupling optical system that is arranged between the plurality of amplifiers and the diffraction grating and superimposes the light beam emitted from each of the plurality of amplifiers on a main surface of the diffraction grating.

8. The semiconductor laser device according to claim 1, comprising:
a semiconductor light emitting element array including the plurality of amplifiers.

9. The semiconductor laser device according to claim 1, further comprising:
a fast axis collimator lens that collimates the light beam in a fast axis direction emitted from each of the plurality of amplifiers.

10. The semiconductor laser device according to claim 9, further comprising:
a 90 degree image rotation optical system array including a plurality of 90 degree image rotation optical systems, each of which interchanges the fast axis direction and a slow axis direction of a light beam emitted from the fast axis collimator lens, the plurality of 90 degree image rotation optical systems being arranged between the fast axis collimator lens and the diffraction grating at intervals equal to intervals of the plurality of amplifiers.
